(19) United States
(12) Patent Application Publication
(10) Pub. No.: US 2010/0313927 A1
(43) Pub. Date: Dec. 16, 2010

(54) APPARATUS FOR CONVERTING ULTRAVIOLET (UV) LIGHT INTO ELECTRICITY

(75) Inventors: Chane-Yu LAI, Changhua County (TW); Sih-Ni CHEN, Taichung County (TW); Hao-Wei CHEN, Taipei City (TW)

Correspondence Address: ROSENBERG, KLEIN & LEE, 3458 ELLICOTT CENTER DRIVE-SUITE 101, ELLICOTT CITY, MD, 21043, US

(73) Assignee: CHANE-YU LAI, CHANGHUA COUNTY (TW)

(21) Appl. No.: 12/814,071

(22) Filed: Jun. 11, 2010

(30) Foreign Application Priority Data
Jun. 15, 2009 (TW) 098210645

(51) Int. Cl. H01L 31/00

(52) U.S. Cl. 136/243

(57) ABSTRACT

An apparatus for converting ultraviolet (UV) light into electricity is disclosed. It includes a UV-light-into-electricity conversion device and an electricity storage. The welding operation zone has a welding apparatus for welding a workpiece. This welding apparatus generates strong UV light during a welding operation. The UV-light-into-electricity conversion device can absorb the UV light and then convert into electricity. Finally, the electricity storage stores the electricity generated by the UV-light-into-electricity conversion device. Hence, it can convert the harmful UV light into useable electricity. The entire structure of this invention is simple. In addition, it is suitable for a fixed operation zone or a movable operation zone during a welding operation.

### BACKGROUND OF THE INVENTION

1. Field of the Invention

The present invention relates to an apparatus for converting ultraviolet (UV) light into electricity. In which, it can convert the harmful UV light into useable electricity. The entire structure of this invention is simple. In addition, it is suitable for a fixed operation zone or a movable operation zone during a welding operation.

2. Description of the Prior Art

In the traditional welding operation, both visible light and UV light are generated. The UV light has higher energy and has greater penetrating rate. UV light is harmful for human. Once the UV light is absorbed by the skin, it is possible to hurt the deoxyribonucleic acid (briefly referred as DNA). When the DNA is damaged, cells will die or will turn into cancer cells (or become a tumour). It is confirmed that UV light and many diseases are highly related such as sunburn, inflammation, erythema, cataract, skin cancer, eye damage, and immune system damage, etc. Thus, it will damage some organs of a human. So, it is required to block the UV light during a welding operation.

In addition, FIG. 7 is a spectrum diagram showing the UV light effective intensity at different wavelength. In which, the welding electric current is 200 A, the welding filler is E6011 (4.0 mm), and the detecting distance is kept as 50 cm. Based on the result in FIG. 7, it can be seen that the energy distribution is mainly concentrated in the range between 250 nm (0.25 μm) and 290 nm (0.29 μm).

Furthermore, with regard to the principle of a solar cell, the solar cell absorbs the sunlight with the wavelength ranging from 0.2 μm˜0.4 μm and then converts into electric energy. When a worker proceeds a welding operation, the energy distribution of the generated light is concentrated in the range between 0.25˜0.29 μm. Of course, such light can be absorbed by the solar cell.

Therefore, it is necessary to research and develop a new technology or device that can convert the UV light into electric energy so as to avoid the waste of the generated light during the welding operation.

### SUMMARY OF THE INVENTION

The object of the present invention is to provide an apparatus for converting ultraviolet (UV) light into electricity. In which, it can convert the harmful UV light into useable electricity. The entire structure of this invention is simple. In addition, it is suitable for a fixed operation zone or a movable operation zone during a welding operation. Especially, this invention can solve the problem about the waste of the generated light during the traditional welding operation.

In order to achieve the above-mentioned object, this invention is provided. An apparatus for converting ultraviolet (UV) light into electricity comprises:

at least one UV-light-into-electricity conversion device being disposed in a welding operation zone, the welding operation zone having a welding apparatus for welding a workpiece, the welding apparatus generating UV light during a welding operation; the UV-light-into-electricity conversion device absorbing the UV light and then converting into electricity; and

an electricity storage connecting to the UV-light-into-electricity conversion device and storing electricity generated by the UV-light-into-electricity conversion device.

### BRIEF DESCRIPTION OF THE DRAWINGS

FIG. 1 is a perspective view of the present invention

FIG. 2 is a view showing the present invention

FIG. 3 is a block diagram of the present invention

FIG. 4 shows another embodiment of the present invention.

FIG. 5 is a cross-sectional view of a selected portion from FIG. 4.

FIG. 6 illustrates an application of the present invention.

FIG. 7 is a spectrum diagram showing the UV light effective intensity at different wavelength.

### DETAILED DESCRIPTION OF THE PREFERRED EMBODIMENT

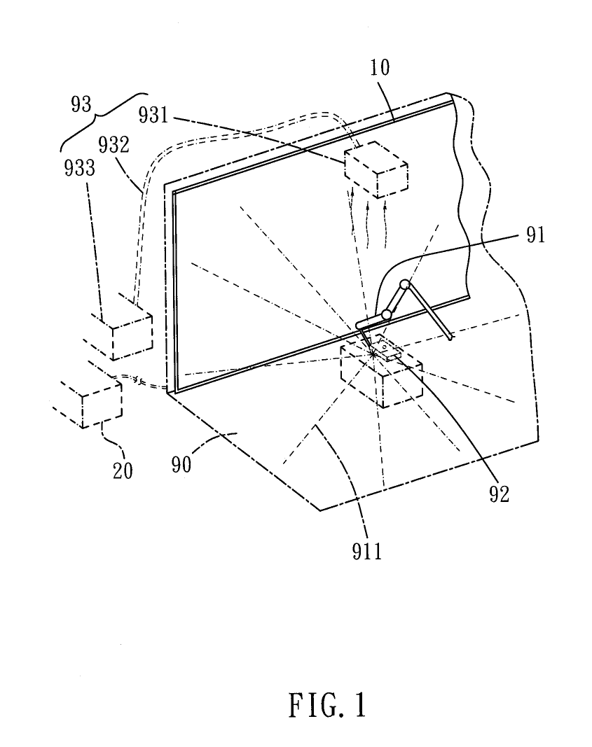

Referring to FIGS. 1, 2, and 3, the present invention is an apparatus for converting ultraviolet (UV) light into electricity. It mainly comprises at least one UV-light-into-electricity conversion device 10 and an electricity storage 20.

About the UV-light-into-electricity conversion device 10, it is disposed in a welding operation zone 90. This welding operation zone 90 has a welding apparatus 91 for welding a workpiece 92. The welding apparatus 91 generates strong UV light 911 during a welding operation. The UV-light-into-electricity conversion device 10 absorbs the UV light 911 and then converts the UV light 911 into electricity 11.

Concerning this electricity storage 20, it connects to the UV-light-into-electricity conversion device 10 and can store electricity 11 which is generated by the UV-light-into-electricity conversion device 10.

Practically, this UV-light-into-electricity conversion device 10 is selected from at least one of zinc oxide structure, silicon structure (already known by the public and widely used in solar cell, especially polysilicon solar cell), silicon thin film structure, cadmium telluride (CdTe) structure, InGaAs structure, and GaAs structure.

The electricity storage 20 can be a rechargeable battery.

The welding operation zone 90 can be a fixed operation zone, a movable operation zone or both.

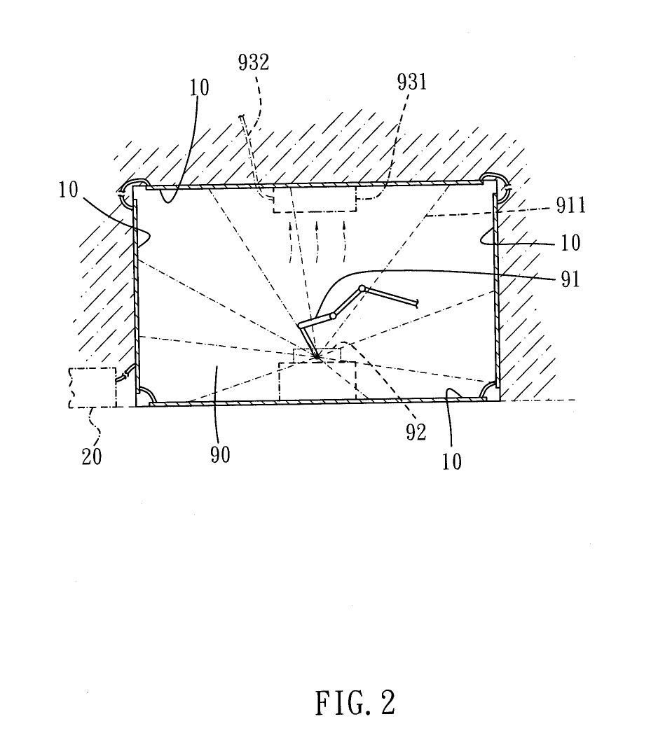

If the welding operation zone 90 is or contains a fixed operation zone (as shown in FIGS. 1 and 2), it shows a welding operation is conducted in one working place (for manufacturing some industrial product). Under this condition, the UV-light-into-electricity conversion device 10 can be mounted on the walls, ceiling, and/or floor of this working place.

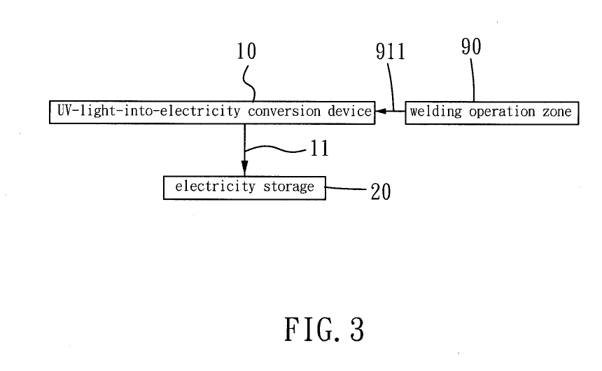

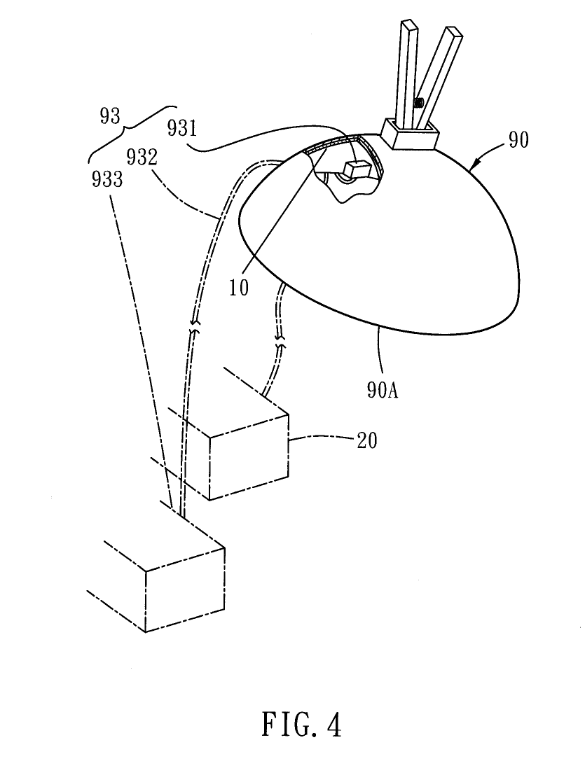

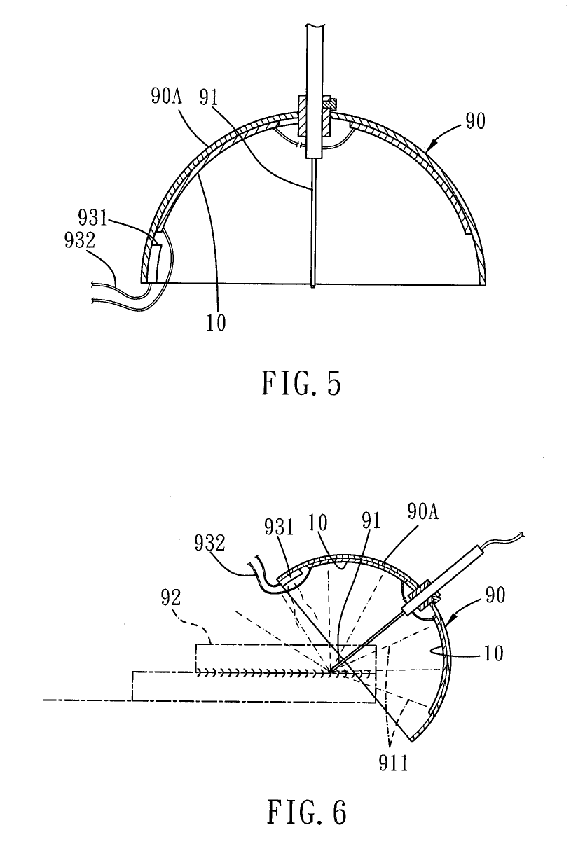

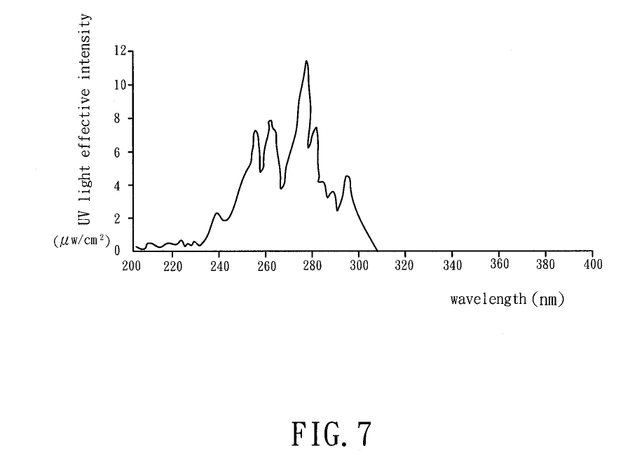

If the welding operation zone 90 is a movable operation zone (as shown in FIGS. 4, 5, and 6), it has (or can be) a hand-held welding device. A welding cover 90A is disposed on the hand-held welding device. The UV-light-into-electricity conversion device 10 is secured on an inner surface of the welding cover 90A. Therefore, most UV light 911 can be absorbed and converted into electricity 11 (see FIG. 3).

No matter which types mentioned above, a sucking device 93 can be added optionally.

The sucking device 93 includes:
a sucking element 931 that is disposed in the fixed operation zone (or disposed in the welding cover 90A in a movable operation zone) for sucking a harmful gas generated in the fixed operation zone 90 during the welding operation;
a ventilating pipe 932 that is disposed with the sucking element 931 for conveying the harmful gas out;
a gas processing portion 933 which is connected with the ventilating pipe 932 for conducting a harmful gas treatment.

Furthermore, with regard to the UV light, it can be classified into the following three types:

(a) UV-A, wavelength roughly ranging from 300-400 nm, or called near UV, can pass through the epidermis and reach the dermis;

(b) UV-B, wavelength roughly ranging from 200-300 nm, or called middle UV, can pass through the epidermis; and

(c) UV-C, wavelength roughly ranging from 10-200 nm, or called far UV, cannot pass through epidermis.

However, no matter which types of UV lights, the UV light is harmful for a human body.

For most solar cells, the major energy conversion is to absorb the light having the wavelength between 200-400 nm of the sunlight. That is, the UV light generated in the welding operation is a good source for energy conversion (of a solar cell), although such UV light usually is possible to hurt human.

Thus, the UV-light-into-electricity conversion device 10 of the present invention can be installed in a welding operation zone 90 directly. Under this condition, the strong UV light generated during the welding operation can be converted into electricity 11 and further be stored by the electricity storage 20.

Of course, the generated electricity 11 can be provided to the welding apparatus 91 directly.

In addition, the sucking element 931 can be secured on an upper position above the welding operation zone 90 (or the welding cover 90A) or an upper portion of the welding operation zone 90 (or the welding cover 90A) so that it can quickly collect the generated harmful gas that moves upward.

The advantages and functions of the present invention can be summarized as follows.

[1] It can convert the harmful UV light into useable electricity. In this invention, the UV-light-into-electricity conversion device is installed in the welding operation zone directly. It can convert the harmful UV light into useable electricity that can be provided to the welding apparatus or to the electricity storage.

[2] The entire structure of this invention is simple. This invention can be done by just adding the UV-light-into-electricity conversion device in the existing working place for welding operation (or in the existing welding apparatus) and adding an electricity storage. So, the entire structure of this invention is simple.

[3] It is suitable for a fixed operation zone or a movable operation zone during a welding operation. Because the UV-light-into-electricity conversion device of this invention is suitable for the fixed operation zone (welding place) or the movable operation zone (hand-held welding apparatus), its application is wide.

While this invention has been particularly shown and described with references to the preferred embodiments thereof, it will be understood by those skilled in the art that various changes or modifications can be made therein without departing from the scope of the invention by the appended claims.

What is claimed is:

1. Apparatus for converting ultraviolet (UV) light into electricity comprises:
at least one UV-light-into-electricity conversion device being disposed in a welding operation zone, said welding operation zone having a welding apparatus for welding a workpiece, said welding apparatus generating strong UV light during a welding operation; said UV-light-into-electricity conversion device absorbing said UV light and then converting into electricity; and
an electricity storage connecting to said UV-light-into-electricity conversion device and storing electricity generated by said UV-light-into-electricity conversion device.

2. The apparatus for converting ultraviolet light into electricity as defined in claim 1, said UV-light-into-electricity conversion device being selected from the group consisting of zinc oxide structure, silicon structure, silicon thin film structure, cadmium telluride structure (CdTe), InGaAs structure, and GaAs structure.

3. The apparatus for converting ultraviolet light into electricity as defined in claim 1, wherein said welding operation zone being a fixed operation zone, a movable operation zone or both.

4. The apparatus for converting ultraviolet light into electricity as defined in claim 1, wherein
said welding operation zone being an movable operation zone;
said movable operation zone having an hand-held welding device, a welding cover being disposed on said hand-held welding device, said UV-light-into-electricity conversion device being secured on an inner surface of said welding cover.

5. The apparatus for converting ultraviolet light into electricity as defined in claim 1, wherein
said welding operation zone includes a fixed operation zone and a movable operation zone;
said movable operation zone having a hand-held welding device, a welding cover being disposed on said hand-held welding device, said UV-light-into-electricity conversion device being secured on an inner surface of said welding cover;
further comprising:
a sucking device including:
a sucking element being disposed in said fixed operation zone for sucking a harmful gas generated in said fixed operation zone during said welding operation;
a ventilating pipe being disposed with said sucking element for conveying said harmful gas out;
a gas processing portion connected with said ventilating pipe for conducting a harmful gas treatment.

6. The apparatus for converting ultraviolet light into electricity as defined in claim 1, wherein
said welding operation zone being a movable operation zone;
said movable operation zone having a hand-held welding device, a welding cover being disposed on said hand-held welding device, said UV-light-into-electricity conversion device being secured on an inner surface of said welding cover;
further comprising:
a sucking device including:
a sucking element being disposed in said welding cover for sucking a harmful gas generated inside said welding cover during said welding operation;
a ventilating pipe being disposed with said sucking element for conveying said harmful gas out;
a gas processing portion connected with said ventilating pipe for conducting a harmful gas treatment.

7. The apparatus for converting ultraviolet light into electricity as defined in claim 1, wherein said electricity storage is a rechargeable battery.
